(19) United States
(12) Patent Application Publication
(10) Pub. No.: US 2025/0002395 A1
(43) Pub. Date: Jan. 2, 2025

(54) ALKALI-FREE GLASS SHEET

(71) Applicant: NIPPON ELECTRIC GLASS CO., LTD., Otsu-shi, Shiga (JP)

(72) Inventor: Mayu NISHIMIYA, Otsu-shi, Shiga (JP)

(73) Assignee: NIPPON ELECTRIC GLASS CO., LTD., Otsu-shi, Shiga (JP)

(21) Appl. No.: 18/708,829

(22) PCT Filed: Oct. 11, 2022
(86) PCT No.: PCT/JP2022/037878

§ 371 Date: May 9, 2024

(30) Foreign Application Priority Data
Nov. 10, 2021 (JP) 2021-183619
Mar. 28, 2022 (JP) 2022-051028

(51) Int. Cl. C03C 3/093

(52) U.S. Cl. CPC C03C 3/093

(57) ABSTRACT

An alkali-free glass sheet of the present invention contains, as a glass composition, in mol %, from 69% to 76% of SiO₂, from 12% to 15% of Al₂O₃, from 0% to 2% of B₂O₃, from 0% to 0.5% of Li₂O+Na₂O+K₂O, from 2% to 10% of MgO, from 2% to 12% of CaO, more than 0% to 5% of SrO, more than 0% to 5% of BaO, and from 12% to 18% of MgO+CaO+SrO+BaO, in which a mol % ratio Al₂O₃/(MgO+CaO+SrO+BaO) is from 0.5 to 1.5, and a mol % ratio SrO/BaO is from 0.3 to 1.6.

### TECHNICAL FIELD

The present invention relates to an alkali-free glass sheet, and particularly relates to an alkali-free glass sheet suitable for an organic EL display.

### BACKGROUND ART

Electronic devices such as organic EL displays are thin, excellent in moving image display, and low in power consumption, and are thus used for applications such as displays of flexible devices and mobile phones.

Glass sheets are widely used as substrates of organic EL displays. Glass sheets for this application are mainly required to have the following characteristics.
(1) In order to prevent alkali ions from diffusing into a semiconductor material formed in a heat treatment step, alkali metal oxides are hardly contained, that is, alkali-free glass (glass in which the content of alkali oxides in the glass composition is 0.5 mol % or less) is used,
(2) in order to reduce the cost of the glass sheet, the glass sheet is formed by an overflow down-draw method in which the surface quality is easily improved, and the glass sheet is excellent in productivity, particularly excellent in meltability and devitrification resistance, and
(3) in LTPS (low temperature poly silicon) process and an oxide TFT process, a strain point is high to reduce thermal shrinkage of the glass sheet.

In addition, information recording media such as magnetic disks and optical disks are used in various information devices.

Glass sheets are widely used as substrates for information recording media in place of known aluminum alloy substrates. In recent years, a magnetic recording medium using an energy assisted magnetic recording system, that is, an energy assisted magnetic recording medium has been studied in order to meet the need for a further increase in recording density. For the energy assisted magnetic recording medium, a glass sheet is also used, and a magnetic layer or the like is formed on the surface of the glass sheet. In the energy assisted magnetic recording medium, an ordered alloy having a large magnetic anisotropy coefficient Ku (hereinafter referred to as “high Ku”) is used as a magnetic material of the magnetic layer.

### CITATION LIST

### Patent Literature

Patent Literature 1: JP2012-106919A
Patent Literature 2: JP2021-086643A

### SUMMARY OF INVENTION

### Technical Problem

Organic EL devices are also widely used in organic EL televisions. There is a strong demand for organic EL televisions to be large and thin, and there is an increasing demand for high-resolution displays such as 8K displays. Thus, glass sheets for these applications are required to have thermal dimensional stability capable of withstanding the demand for high resolution while being increased in size and reduced in thickness. Further, organic EL televisions are required to be low in cost in order to reduce the difference in price from liquid crystal displays, and glass sheets are also required to be low in cost. However, when a glass sheet is increased in size and reduced in thickness, the glass sheet easily bends, and the manufacturing cost increases.

A glass sheet formed by a glass manufacturer undergoes steps such as cutting, annealing, inspection, and cleaning, and during these steps, the glass sheet is loaded into and unloaded from a cassette in which a plurality of shelves are formed. In this cassette, opposite sides of the glass sheet are usually placed on shelves formed on the left and right inner surfaces and held in a horizontal direction. However, since a large and thin glass sheet has a large deflection amount, when the glass sheet is loaded into the cassette, a part of the glass sheet comes into contact with the cassette and is damaged, or when the glass sheet is unloaded, the glass sheet is likely to swing greatly and become unstable. Since a cassette having such a form is also used by an electronic device manufacturer, a similar problem occurs. To solve this problem, it is effective to increase the Young's modulus of the glass sheet to reduce the deflection amount.

In addition, as described above, in the LTPS or oxide TFT process for obtaining a high-resolution display, it is necessary to increase the strain point of the glass sheet in order to reduce the thermal shrinkage of the large glass sheet.

However, in increasing the Young's modulus and the strain point of the glass sheet, the balance of the glass composition is lost, and the productivity decreases, and particularly, the devitrification resistance remarkably decreases, and the liquidus viscosity increases. Thus, the glass sheet cannot be formed by the overflow down-draw method. In addition, the meltability tends to decrease, the forming temperature of the glass tends to increase, and the life of the formed body tends to be shortened. As a result, the cost of an original sheet for the glass sheet increases.

In addition, the glass sheet for a magnetic recording medium is required to have high rigidity (Young's modulus) in order not to cause large deformation during high-speed rotation. More specifically, in a disk-shaped magnetic recording medium, information is written and read in the direction of rotation while the medium is rotated at a high speed around the central axis and the magnetic head is moved in the radial direction. In recent years, the number of rotations for increasing the write speed and the read speed has been increasing from 5400 rpm to 7200 rpm and further to 10000 rpm. In a disk-shaped magnetic recording medium, positions for recording information are assigned in advance in accordance with the distance from the central axis. Thus, when the glass sheet is deformed during rotation, a positional deviation of the magnetic head occurs, and accurate reading becomes difficult.

In recent years, DFH (dynamic flying height) mechanism has been mounted on a magnetic head to achieve a remarkable reduction in the gap between a recording and reproducing element portion of the magnetic head and the surface of the magnetic recording medium (reduction in flying height), to achieve a further increase in recording density. The DFH mechanism is a mechanism in which a heating unit such as an extremely small heater is provided in the vicinity of the recording and reproducing element portion of the magnetic head, and only the periphery of the element portion is thermally expanded toward a medium surface direction. By providing such a mechanism, the distance between the magnetic head and the magnetic layer of the medium is reduced, and thus a signal of a smaller magnetic particle can be picked up, which enables achievement of an increase in recording density. On the other hand, since the gap between the recording and reproducing element portion of the magnetic head and the surface of the magnetic recording medium becomes extremely small, for example, 2 nm or less, the magnetic head may collide with the surface of the magnetic recording medium even with a slight impact. This tendency becomes more remarkable as the rotation speed becomes higher. Thus, during the high-speed rotation, it is important to prevent the occurrence of bending or flapping (fluttering) of the glass sheet that causes the collision.

In addition, in order to increase the degree of ordering (regularity) of the magnetic layer to achieve a high Ku, a base material including a glass sheet may be subjected to a heat treatment at a high temperature of about 800° C. during or before or after formation of the magnetic layer. Since the higher the recording density is, the higher the temperature is required in this heat treatment, the glass sheet is required to have higher heat resistance, that is, a higher strain point than a known glass sheet for a magnetic recording medium. After the magnetic layer is formed, laser irradiation may be performed on the base material including a glass sheet. Such heat treatment and laser irradiation are also aimed at increasing the annealing temperature and coercive force of the magnetic layer containing a FePt-based alloy or the like.

However, as described above, in increasing the Young's modulus and the strain point of the glass sheet, the balance of the glass composition is lost, and the productivity decreases, and particularly, the devitrification resistance remarkably decreases, and the liquidus viscosity increases. Thus, the glass sheet cannot be formed by the overflow down-draw method. In addition, the meltability tends to decrease, the forming temperature of the glass tends to increase, and the life of the formed body tends to be shortened. As a result, the cost of an original sheet for the glass sheet increases.

Therefore, the present invention has been made in view of the above circumstances, and a technical object thereof is to provide an alkali-free glass sheet that is excellent in productivity and sufficiently high in strain point and Young's modulus.

### Solution to Problem

As a result of repeating various experiments, the inventor of the present invention has found that the above technical problem can be solved by strictly regulating the glass composition of an alkali-free glass sheet, and proposes the finding as the present invention.

That is, (1) an alkali-free glass sheet of the present invention contains, as a glass composition, in mol %, from 69% to 76% of SiO₂, from 12% to 15% of Al₂O₃, from 0% to 2% of B₂O₃, from 0% to 0.5% of Li₂O+Na₂O+K₂O, from 2% to 10% of MgO, from 2% to 12% of CaO, more than 0% to 5% of SrO, more than 0% to 5% of BaO, and from 12% to 18% of MgO+CaO+SrO+BaO, in which a mol % ratio Al₂O₃/(MgO+CaO+SrO+BaO) is from 0.5 to 1.5, and a mol % ratio SrO/BaO is from 0.3 to 1.6. Here, “Li₂O+Na₂O+K₂O” refers to the total amount of Li₂O, Na₂O, and K₂O. “MgO+CaO+SrO+BaO” refers to the total amount of MgO, CaO, SrO, and BaO. “Al₂O₃/(MgO+CaO+SrO+BaO)” is a value obtained by dividing the mol % content of Al₂O₃ by the total amount of MgO, CaO, SrO, and BaO. “SrO/BaO” is a value obtained by dividing the mol % content of SrO by the mol % content of BaO.

(2) It is preferable that the alkali-free glass sheet in the above (1) contains, as a glass composition, in mol %, from 70% to 75% of SiO₂, from 13% to 14% of Al₂O₃, from 0% to 1% of B₂O₃, from 0% to 0.1% of Li₂O+Na₂O+K₂O, from 2% to 9% of MgO, from 2% to 11% of CaO, more than 0% to 4% of SrO, more than 0% to 4% of BaO, and from 13% to 17% of MgO+CaO+SrO+BaO, in which the mol % ratio Al₂O₃/(MgO+CaO+SrO+BaO) is from 0.8 to 1.2, and the mol % ratio SrO/BaO is from 0.6 to 1.5.

(3) It is preferable that the alkali-free glass sheet in the above (1) contains, as a glass composition, in mol %, from 69% to 76% of SiO₂, from 12.6% to 15% of Al₂O₃, from 0% to 1% of B₂O₃, from 0% to 0.5% of Li₂O+Na₂O+K₂O, from 2% to 10% of MgO, from 2% to 12% of CaO, more than 0% to 5% of SrO, more than 0% to 5% of BaO, from 0% to 0.2% of ZnO, and from 12% to 18% of MgO+CaO+SrO+BaO, in which the mol % ratio Al₂O₃/(MgO+CaO+SrO+BaO) is from 0.5 to 1.5, the mol % ratio SrO/BaO is from 0.6 to 1.6, and MgO+CaO+SrO+BaO—Al₂O₃ is from −1.5% to 4%. Here, “MgO+CaO+SrO+BaO—Al₂O₃” is a value obtained by subtracting the mol % content of Al₂O₃ from the total amount of MgO, CaO, SrO, and BaO.

(4) It is preferable that the alkali-free glass sheet in the above (3) contains, as a glass composition, in mol %, from 70% to 76% of SiO₂, from 13% to 15% of Al₂O₃, from 0% to 1% of B₂O₃, from 0% to 0.5% of Li₂O+Na₂O+K₂O, from 2% to 10% of MgO, from 2% to 12% of CaO, more than 0% to 5% of SrO, more than 0% to 5% of BaO, from 0% to 0.2% of ZnO, and from 12% to 18% of MgO+CaO+SrO+BaO, in which the mol % ratio Al₂O₃/(MgO+CaO+SrO+BaO) is from 0.5 to 1.5, the mol % ratio SrO/BaO is from 0.6 to 1.6, and MgO+CaO+SrO+BaO—Al₂O₃ is from −1.5% to 4%.

(5) It is preferable that, in the alkali-free glass sheet in the above (1) to (4), the content of BaO is from 1.5 mol % to 2.5 mol %.

(6) It is preferable that, in the alkali-free glass sheet in the above (1) to (5), the glass composition does not substantially contain As₂O₃ and Sb₂O₃, and further contains from 0.001 mol % to 1 mol % of SnO₂. Here, “does not substantially contain As₂O₃” refers to a case where the content of As₂O₃ is 0.05 mol % or less. “Does not substantially contain Sb₂O₃” refers to a case where the content of Sb₂O₃ is 0.05 mol % or less.

(7) It is preferable that, in the alkali-free glass sheet in the above (1) to (6), a Young's modulus is 82 GPa or more, a strain point is 740° C. or higher, and a liquidus temperature is 1370° C. or lower. Here, the “Young's modulus” refers to a value measured by a bending resonance method. Note that 1 GPa corresponds to about 101.9 Kgf/mm². The “strain point” refers to a value measured based on the method in ASTM C336. The “liquidus temperature” refers to a temperature at which crystals precipitate after a glass powder that has passed through a standard 30-mesh sieve (500 μm) and remained on a 50-mesh sieve (300 μm) is charged into a platinum boat and then kept in a temperature gradient furnace for 24 hours.

(8) It is preferable that, in the alkali-free glass sheet in the above (1) to (7), the strain point is 750° C. or higher.

(9) It is preferable that, in the alkali-free glass sheet in the above (1) to (8), the Young's modulus is more than 83 GPa.

(10) It is preferable that, in the alkali-free glass sheet in the above (1) to (9), an average thermal expansion coefficient in a temperature range of from 30° C. to 380° C. is from 30×10⁻⁷/° C. to 50×10⁻⁷/° C. Here, the “average thermal expansion coefficient in a temperature range of from 30° C. to 380° C.” can be measured with a dilatometer.

(11) It is preferable that, in the alkali-free glass sheet in the above (1) to (10), the liquidus viscosity is 10^{4.2} dPa·s or more. Here, the “liquidus viscosity” refers to a viscosity of glass at a liquidus temperature and can be measured by a platinum sphere pull up method.

(12) It is preferable that, in the alkali-free glass sheet in the above (1) to (11), an annealing point is 810° C. or higher. Here, the “annealing point” refers to a value measured based on the method in ASTM C336.

(13) It is preferable that the alkali-free glass sheet in the above (1) to (12) is used for an organic EL device.

(14) It is preferable that the alkali-free glass sheet in the above (1) to (12) is used for a magnetic recording medium.

### BRIEF DESCRIPTION OF DRAWING

FIG. 1 is a top perspective view showing an example of the shape of a glass substrate for a magnetic recording medium.

### DESCRIPTION OF EMBODIMENTS

An alkali-free glass sheet of the present invention contains, as a glass composition, in mol %, from 69% to 76% of SiO₂, from 12% to 15% of Al₂O₃, from 0% to 2% of B₂O₃, from 0% to 0.5% of Li₂O+Na₂O+K₂O, from 2% to 10% of MgO, from 2% to 12% of CaO, more than 0% to 5% of SrO, more than 0% to 5% of BaO, and from 12% to 18% of MgO+CaO+SrO+BaO, in which a mol % ratio Al₂O₃/(MgO+CaO+SrO+BaO) is from 0.5 to 1.5, and a mol % ratio SrO/BaO is from 0.3 to 1.6. The reason for limiting the content of each component as described above is as follows. Note that in the description of the content of each component, “%” represents “mol %” unless otherwise indicated.

SiO₂ is a component that forms a glass network. When the content of SiO₂ is too low, the thermal expansion coefficient increases, and the density increases. Thus, the lower limit amount of SiO₂ is preferably 69%, more preferably 69.2%, further preferably 69.4%, further preferably 69.6%, further preferably 69.8%, further preferably 70%, further preferably 70.2%, further preferably 70.4%, further preferably 70.6%, further preferably 70.8%, and particularly preferably 71%. When the content of SiO₂ is too high, the Young's modulus decreases, the viscosity in high temperature further increases, the amount of heat required at the time of melting increases, the melting cost increases, and remnants of the introduced raw material SiO₂ occur, which may cause a decrease in yield. In addition, devitrified crystals such as cristobalite tend to precipitate, and the liquidus viscosity tends to decrease. Thus, the upper limit amount of SiO₂ is preferably 76%, more preferably 75.8%, further preferably 75.6%, further preferably 75.4%, further preferably 75.2%, further preferably 75%, further preferably 74.8%, further preferably 74.6%, and particularly preferably 74.4%.

Al₂O₃ is a component that forms a glass network, a component that increases the Young's modulus, and is a component that further increases the strain point. When the content of Al₂O₃ is too low, the Young's modulus tends to decrease, and the strain point tends to decrease. Thus, the lower limit amount of Al₂O₃ is preferably 12%, more preferably 12.2%, further preferably 12.4%, further preferably more than 12.4%, further preferably 12.5%, further preferably 12.6%, further preferably 12.8%, further preferably more than 12.8%, further preferably 12.9%, further preferably 13%, further preferably more than 13%, further preferably 13.1%, further preferably 13.2%, and particularly preferably 13.3%. When the content of Al₂O₃ is too high, devitrified crystals such as mullite tend to precipitate, and the liquidus viscosity tends to decrease. Thus, the upper limit amount of Al₂O₃ is preferably 15%, more preferably 14.8%, further preferably 14.6%, further preferably 14.4%, further preferably 14.2%, further preferably 14%, further preferably 13.9%, further preferably 13.8%, further preferably 13.7%, and particularly preferably 13.6%.

The mol % ratio SiO₂/Al₂O₃ is an important component ratio for increasing the strain point and lowering the viscosity in high temperature. When the mol % ratio SiO₂/Al₂O₃ is too small, the strain point tends to decrease. Thus, the lower limit of the mol % ratio SiO₂/Al₂O₃ is preferably 4.5, more preferably 4.7, further preferably 4.9, further preferably 5, further preferably 5.1, further preferably more than 5.1, further preferably 5.2, further preferably more than 5.2, and particularly preferably 5.3. When the mol % ratio SiO₂/Al₂O₃ is too large, the viscosity in high temperature increases, and the manufacturing cost of the glass sheet tends to increase. Thus, the upper limit of the mol % ratio SiO₂/Al₂O₃ is preferably 6.5, more preferably 6.3, further preferably 6.1, further preferably 6, further preferably 5.9, further preferably 5.8, and particularly preferably 5.7.

When B₂O₃ is contained, the effect of increasing the meltability and the devitrification resistance can be obtained. Thus, the lower limit amount of B₂O₃ is preferably 0%, more preferably more than 0%, more preferably 0.1%, further preferably 0.2%, further preferably 0.3%, further preferably 0.4%, further preferably 0.5%, and particularly preferably 0.6%. When the content of B₂O₃ is too high, the Young's modulus and the strain point tend to decrease. Thus, the upper limit amount of B₂O₃ is preferably 2%, more preferably more than 1.9%, further preferably 1.8%, further preferably 1.7%, further preferably 1.6%, further preferably 1.5%, further preferably 1.4%, further preferably 1.3%, further preferably 1.2%, and particularly preferably 1%.

The mol % ratio SiO₂/(Al₂O₃—B₂O₃) is a component ratio related to the density and the viscosity in high temperature. When the mol % ratio SiO₂/(Al₂O₃—B₂O₃) is too small, the density tends to increase, and as a result, the glass tends to bend. Thus, the lower limit amount of the mol % ratio SiO₂/(Al₂O₃—B₂O₃) is preferably 3, more preferably 3.5, further preferably 3.8, further preferably 4, further preferably 4.3, further preferably 4.5, further preferably 4.8, further preferably 5, and particularly preferably more than 5. When the mol % ratio SiO₂/(Al₂O₃—B₂O₃) is too large, the viscosity in high temperature increases, and the manufacturing cost of the glass sheet tends to increase. Thus, the upper limit amount of the mol % ratio SiO₂/Al₂O₃ is preferably 8, more preferably 7.8, further preferably 7.5, further preferably 7.3, further preferably 7, further preferably 6.8, and particularly preferably 6.5.

Li₂O, Na₂O, and K₂O are components inevitably mixed from the glass raw material, and the total amount thereof is from 0% to 0.5%, preferably from 0% to 0.1%, more preferably from 0% to 0.09%, further preferably from 0.005% to 0.08%, further preferably from 0.008% to 0.06%, and particularly preferably from 0.01% to 0.05%. When the total amount of Li₂O, Na₂O, and K₂O is too high, alkali ions may diffuse into a semiconductor material formed during a heat treatment step. Note that the individual contents of Li₂O, Na₂O, and K₂O are each preferably from 0% to 0.3%, more preferably from 0% to 0.1%, further preferably from 0% to 0.08%, further preferably from 0% to 0.07%, further preferably from 0% to 0.05%, and particularly preferably from 0.001% to 0.04%.

MgO is a component that remarkably increases the Young's modulus among alkaline earth metal oxides. When the content of MgO is too low, the meltability and the Young's modulus tend to decrease. Thus, the lower limit amount of MgO is preferably 2%, more preferably more than 2.1%, further preferably 2.3%, further preferably 2.5%, further preferably 2.8%, further preferably 3%, further preferably 3.2%, further preferably 3.5%, further preferably 3.8%, and particularly preferably 4%. When the content of MgO is too high, devitrified crystals such as mullite tend to precipitate, and the liquidus viscosity tends to decrease. Thus, the upper limit amount of MgO is preferably 10%, more preferably 9.8%, further preferably 9.5%, further preferably 9.3%, further preferably 9%, further preferably less than 9%, further preferably 8.8%, further preferably 8.6%, further preferably 8.4%, further preferably 8.2%, further preferably 8%, and particularly preferably 7.8%.

CaO is a component that decreases the viscosity in high temperature and remarkably increases the meltability without lowering the strain point. It is also a component that increases the Young's modulus. When the content of CaO is too low, the meltability tends to decrease. Thus, the lower limit amount of CaO is preferably 2%, more preferably 2.5%, further preferably 2.8%, further preferably 3%, further preferably 3.3%, further preferably 3.5%, further preferably 3.8%, further preferably 4%, and particularly preferably 4.5%. When the content of CaO is too high, the liquidus temperature increases. Thus, the upper limit amount of CaO is preferably 12%, more preferably 11.9%, further preferably 11.8%, further preferably 11.6%, further preferably 11.5%, further preferably 11.4%, further preferably 11.3%, and particularly preferably 11%.

The mol % ratio MgO/CaO is a component ratio related to the density and the liquidus viscosity. When the mol % ratio MgO/CaO is too small, the density tends to increase, and as a result, the glass tends to bend. Thus, the lower limit amount of the mol % ratio MgO/CaO is preferably 0.1, more preferably 0.2, further preferably 0.3, further preferably 0.4, further preferably 0.5, further preferably 0.6, further preferably 0.7, and particularly preferably 0.8. When the mol % ratio MgO/CaO is too large, the liquidus viscosity decreases, and the manufacturing cost of the glass sheet tends to increase. Thus, the upper limit amount of the mol % ratio MgO/CaO is preferably 4, more preferably 3.5, further preferably 3.2, further preferably 3, further preferably 2.8, further preferably 2.6, further preferably 2.5, further preferably 2.2, and particularly preferably 2.

SrO is a component that increases the devitrification resistance, decreases the viscosity in high temperature, and increases the meltability without lowering the strain point. It is also a component that reduces a decrease in liquidus viscosity. Thus, the lower limit amount of SrO is preferably more than 0%, more preferably 0.2%, further preferably 0.4%, further preferably 0.6%, further preferably 0.8%, further preferably 1%, further preferably 1.2%, further preferably more than 1.2%, and particularly preferably 1.5%. When the content of SrO is too high, the thermal expansion coefficient and the density tend to increase. Thus, the upper limit amount of SrO is preferably 5%, more preferably less than 5%, further preferably 4.8%, further preferably 4.6%, further preferably 4.4%, further preferably 4.2%, further preferably 4%, further preferably 3.8%, further preferably 3.6%, further preferably 3.4%, and particularly preferably 3.2%.

BaO is a component that increases the devitrification resistance. Thus, the lower limit amount of BaO is preferably more than 0%, more preferably 0.2%, further preferably 0.4%, further preferably 0.6%, further preferably 0.8%, further preferably 1%, further preferably 1.2%, further preferably more than 1.2%, and particularly preferably 1.5%. When the content of BaO is too high, the Young's modulus tends to decrease, and the density tends to increase. As a result, the specific Young's modulus increases, and the glass sheet tends to bend. Thus, the upper limit amount of BaO is preferably 5%, more preferably less than 5%, further preferably 4.8%, further preferably 4.6%, further preferably 4.4%, further preferably 4.2%, further preferably 4%, further preferably 3.8%, further preferably 3.6%, further preferably 3.4%, further preferably 3.2%, further preferably 3.0%, further preferably 2.8%, further preferably 2.6%, and particularly preferably 2.5%.

The mol % ratio SrO/BaO is an important component ratio for increasing the Young's modulus and the strain point. When the mol % ratio SrO/BaO is too small, the Young's modulus tends to decrease. Thus, the lower limit amount of the mol % ratio SrO/BaO is preferably 0.3, more preferably 0.4, further preferably 0.45, further preferably 0.5, further preferably 0.55, further preferably 0.6, further preferably 0.62, further preferably 0.64, further preferably 0.66, further preferably 0.68, further preferably 0.7, further preferably 0.72, and particularly preferably 0.75. When the mol % ratio SrO/BaO is too large, the strain point tends to decrease. Thus, the upper limit amount of the mol % ratio SrO/BaO is preferably 1.6, more preferably less than 1.6, further preferably 1.55, further preferably 1.5, and particularly preferably less than 1.5.

MgO, CaO, SrO, and BaO are components that increase the density and the thermal expansion coefficient. When the content of MgO+CaO+SrO+BaO is too low, the thermal expansion coefficient tends to decrease. Thus, the lower limit amount of MgO+CaO+SrO+BaO is preferably 12%, more preferably more than 12%, further preferably 12.1%, further preferably more than 12.1%, further preferably 12.2%, further preferably 12.4%, further preferably 12.6%, further preferably 12.8%, and particularly preferably 13%. When the content of MgO+CaO+SrO+BaO is too high, the density tends to increase. Thus, the upper limit amount of MgO+CaO+SrO+BaO is preferably 18%, more preferably less than 18%, further preferably 17.9%, further preferably 17.7%, further preferably 17.5%, further preferably 17.3%, and particularly preferably 17%.

The mol % ratio (MgO+CaO)/(SrO+BaO) is a component ratio related to the density. When the mol % ratio (MgO+CaO)/(SrO+BaO) is too small, the density tends to increase, and as a result, the glass tends to bend. Thus, the lower limit amount of the mol % ratio (MgO+CaO)/(SrO+BaO) is preferably 0.1, more preferably 0.5, further preferably 0.8, further preferably 1, further preferably 1.2, further preferably 1.5, further preferably 1.8, further preferably 2, and particularly preferably 2.2. When the mol % ratio (MgO+CaO)/(SrO+BaO) is too large, the liquidus temperature tends to increase, and the manufacturing cost tends to increase. Thus, the upper limit amount of the mol % ratio (MgO+CaO)/(SrO+BaO) is preferably 1600, more preferably 1500, further preferably 1000, further preferably 900, further preferably 800, further preferably 750, further preferably 700, further preferably 600, and particularly preferably 500.

The mol % ratio Al₂O₃/(MgO+CaO+SrO+BaO) is an important component ratio for increasing the strain point and lowering the viscosity in high temperature. When the mol % ratio Al₂O₃/(MgO+CaO+SrO+BaO) is too small, the strain point tends to decrease. Thus, the lower limit amount of the mol % ratio Al₂O₃/(MgO+CaO+SrO+BaO) is preferably 0.5, more preferably 0.52, further preferably 0.54, further preferably 0.56, further preferably 0.58, further preferably 0.6, further preferably 0.62, further preferably 0.64, further preferably 0.66, further preferably 0.68, further preferably 0.7, further preferably 0.72, further preferably 0.74, further preferably 0.76, further preferably 0.78, and particularly preferably 0.8. When the mol % ratio Al₂O₃/(MgO+CaO+SrO+BaO) is too large, the viscosity in high temperature increases, and the manufacturing cost of the glass sheet tends to increase. Thus, the upper limit amount of the mol % ratio Al₂O₃/(MgO+CaO+SrO+BaO) is preferably 1.5, more preferably 1.45, further preferably 1.4, further preferably 1.35, further preferably 1.3, further preferably 1.25, and particularly preferably 1.2.

(MgO+CaO+SrO+BaO)—Al₂O₃ is an important component ratio for increasing the strain point and lowering the viscosity in high temperature. When (MgO+CaO+SrO+BaO)—Al₂O₃ is too small, the viscosity in high temperature increases, and the manufacturing cost of the glass sheet tends to increase. Thus, the lower limit amount of (MgO+CaO+SrO+BaO)—Al₂O₃ is preferably −2, more preferably −1.5, further preferably −1.3, further preferably −1, further preferably −0.5, further preferably −0.3, further preferably −0.2, further preferably −0.1, further preferably 0, further preferably 0.1, further preferably 0.2, further preferably 0.3, further preferably 0.4, further preferably 0.5, further preferably 0.6, further preferably 0.7, further preferably 0.8, further preferably 0.9, and particularly preferably 1. When (MgO+CaO+SrO+BaO)—Al₂O₃ is too large, the strain point tends to decrease. Thus, the upper limit amount of (MgO+CaO+SrO+BaO)—Al₂O₃ is preferably 4, more preferably 3.5, further preferably 3.3, further preferably 3.1, further preferably 3, further preferably 2.9, further preferably 2.8, further preferably 2.7, further preferably 2.6, further preferably 2.5, and particularly preferably 2.4.

The mol % ratio (Al₂O₃+MgO)/(B₂O₃+SrO+BaO) is a component ratio related to the density and the Young's modulus. When the mol % ratio (Al₂O₃+MgO)/(B₂O₃+SrO+BaO) is too small, the density tends to increase, the Young's modulus tends to decrease, and as a result, the glass tends to bend. Thus, the lower limit amount of the mol % ratio (Al₂O₃+MgO)/(B₂O₃+SrO+BaO) is preferably 0.1, more preferably 0.5, further preferably 0.8, further preferably 1, further preferably 1.2, further preferably 1.5, further preferably 1.8, further preferably 2, further preferably 2.2, further preferably 2.5, further preferably 2.9, further preferably 3, further preferably 3.3, further preferably 3.5, further preferably 3.8, further preferably 4, and particularly preferably 4.2. When the mol % ratio (Al₂O₃+MgO)/(B₂O₃+SrO+BaO) is too large, the liquidus temperature tends to increase, and the manufacturing cost tends to increase. Thus, the upper limit amount of the mol % ratio (Al₂O₃+MgO)/(B₂O₃+SrO+BaO) is preferably 1200, more preferably 1100, further preferably 1000, further preferably 900, further preferably 800, further preferably 750, further preferably 700, further preferably 600, and particularly preferably 500.

ZnO is not an essential component, but is a component that increases the Young's modulus. Thus, the lower limit amount of ZnO is preferably 0%, more preferably more than 0%, further preferably more than 0.001%, and particularly preferably 0.001% or more. When ZnO is too much, the glass tends to undergo devitrification. Thus, the upper limit amount of ZnO is preferably 2%, more preferably 1%, further preferably 0.5%, further preferably less than 0.5%, further preferably 0.4%, further preferably less than 0.4%, further preferably 0.3%, further preferably less than 0.3%, further preferably 0.2%, and particularly preferably less than 0.2%.

Suitable content ranges of the respective components can be appropriately combined to obtain a suitable glass composition range, and among them, in order to optimize the effect of the present invention, it is particularly preferable that the glass composition contains, in mol %, from 70% to 75% of SiO₂, from 13% to 14% of Al₂O₃, from 0% to 1% of B₂O₃, from 0% to 0.1% of Li₂O+Na₂O+K₂O, from 2% to 9% of MgO, from 2% to 11% of CaO, more than 0% to 4% of SrO, more than 0% to 4% of BaO, and from 13% to 17% of MgO+CaO+SrO+BaO, in which the mol % ratio Al₂O₃/(MgO+CaO+SrO+BaO) is from 0.8 to 1.2, and the mol % ratio SrO/BaO is from 0.6 to 1.5.

In addition, it is particularly preferable that, the glass composition contains, in mol %, from 69% to 76% of SiO₂, from 12.6% to 15% of Al₂O₃, from 0% to 1% of B₂O₃, from 0% to 0.5% of Li₂O+Na₂O+K₂O, from 2% to 10% of MgO, from 2% to 12% of CaO, more than 0% to 5% of SrO, more than 0% to 5% of BaO, from 0% to 0.2% of ZnO, and from 12% to 18% of MgO+CaO+SrO+BaO, in which the mol % ratio Al₂O₃/(MgO+CaO+SrO+BaO) is from 0.5 to 1.5, the mol % ratio SrO/BaO is from 0.6 to 1.6, and MgO+CaO+SrO+BaO—Al₂O₃ is from −1.5% to 4%.

In addition to the above components, the following components may be added as an optional component, for example. Note that the total content of components other than the above components is preferably 5% or less, and particularly preferably 1% or less, from the viewpoint of accurately achieving the effects of the present invention.

P₂O₅ is a component that increases the strain point, and is a component that can remarkably reduce precipitation of alkaline earth aluminosilicate-based devitrified crystals such as anorthite. However, when a large amount of P₂O₅ is contained, the glass tends to undergo phase separation. The content of P₂O₅ is preferably from 0% to 2.5%, more preferably from 0% to 1.5%, further preferably from 0% to 0.5%, further preferably from 0% to 0.3%, and particularly preferably from 0% to less than 0.1%.

TiO₂ is a component that lowers the viscosity in high temperature and increases the meltability, and is a component that prevents solarization. However, when a large amount of TiO₂ is contained, the glass is colored, and the transmittance tends to decrease. The content of TiO₂ is preferably from 0% to 2.5%, more preferably from 0.0005% to 1%, further preferably from 0.001% to 0.5%, and particularly preferably from 0.005% to 0.1%.

Fe₂O₃ is a component inevitably mixed from the glass raw material, and is a component that decreases the electrical resistivity. The content of Fe₂O₃ is preferably from 0 ppm by mass to 300 ppm by mass, more preferably from 50 ppm by mass to 250 ppm by mass, and particularly preferably from 80 ppm by mass to 200 ppm by mass. When the content of Fe₂O₃ is too low, the raw material cost tends to increase. When the content of Fe₂O₃ is too high, the electrical resistivity of the molten glass increases, and it is difficult to perform electrical melting.

ZrO₂ is a component that increases the Young's modulus. However, when a large amount of ZrO₂ is contained, the glass tends to undergo devitrification. The content of ZrO₂ is preferably from 0% to 2.5%, more preferably from 0.0005% to 1%, further preferably from 0.001% to 0.5%, and particularly preferably from 0.005% to 0.1%.

Y₂O₃, Nb₂O₅, and La₂O₃ have a function of increasing the strain point, the Young's modulus, and the like. The total amount and individual content of these components are preferably from 0% to 5%, more preferably from 0% to 1%, further preferably from 0% to 0.5%, and particularly preferably more than 0% and less than 0.5%. When the total amount and individual content of Y₂O₃, Nb₂O₅, and La₂O₃ are too high, the density and the raw material cost tend to increase.

SnO₂ is a component having a good fining action in a high temperature range, is a component that increases the strain point, and is a component that decreases the viscosity in high temperature. The content of SnO₂ is preferably from 0% to 1%, more preferably from 0.001% to 1%, further preferably from 0.01% to 0.5%, and particularly preferably from 0.05% to 0.3%. When the content of SnO₂ is too high, devitrified crystals of SnO₂ tend to precipitate. Note that, when the content of SnO₂ is lower than 0.001%, it is difficult to obtain the above effects.

As described above, SnO₂ is suitable as a fining agent. However, as long as the glass characteristics are not impaired, F, SO₃, C, or a metal powder such as Al or Si may be added up to 5% for each (preferably up to 1%, particularly up to 0.5%), instead of SnO₂ or together with SnO₂, as fining agents. CeO₂, F, and the like can also be added as fining agents up to 5% for each (preferably up to 1%, particularly up to 0.5%).

As₂O₃ and Sb₂O₃ are also effective as fining agents. However, As₂O₃ and Sb₂O₃ are components that increase the burden to the environment. As₂O₃ is also a component that decreases the solarization resistance. Thus, the alkali-free glass sheet of the present invention preferably does not substantially contain these components.

Cl is a component that facilitates initial melting of a glass batch. In addition, the addition of Cl can facilitate the action of the fining agent. As a result, it is possible to extend the life of the glass manufacturing kiln while reducing the melting cost. However, when the content of Cl is too high, the strain point tends to decrease. Thus, the content of Cl is preferably from 0% to 3%, more preferably from 0.0005% to 1%, and particularly preferably from 0.001% to 0.5%. Note that, as a raw material for introducing Cl, a raw material such as a chloride of an alkaline earth metal oxide, an example being strontium chloride, or aluminum chloride can be used.

The alkali-free glass sheet of the present invention preferably has the following characteristics.

The average thermal expansion coefficient in a temperature range of from 30° C. to 380° C. is preferably from 30×10⁻⁷/° C. to 50×10⁻⁷/° C., more preferably from 30×10⁻⁷/° C. to 48×10⁻⁷/° C., further preferably from 30×10⁻⁷/° C. to 45×10⁻⁷/° C., further preferably from 31×10⁻⁷/° C. to 42×10⁻⁷/° C., and particularly preferably from 32×10⁻⁷/° C. to 40×10⁻⁷/° C. This makes it easy to match the thermal expansion coefficient of Si used in TFT.

The Young's modulus is preferably 82 GPa or more, more preferably more than 82 GPa, further preferably 82.3 GPa or more, further preferably 82.5 GPa or more, further preferably 82.8 GPa or more, further preferably 83 GPa or more, further preferably 83.3 GPa or more, further preferably 83.5 GPa or more, further preferably 83.8 GPa or more, and particularly preferably 84 GPa or more. A preferred upper limit value is 120 GPa. When the Young's modulus is too low, defects due to bending of the glass sheet are likely to occur.

The strain point is preferably 740° C. or higher, more preferably 745° C. or higher, further preferably 750° C. or higher, further preferably 752° C. or higher, further preferably 755° C. or higher, further preferably 758° C. or higher, and particularly preferably 760° C. or higher. A preferred upper limit value is 820° C. This makes it possible to reduce the thermal shrinkage of the glass sheet in the LTPS process.

The annealing point is preferably 800° C. or higher, more preferably 805° C. or higher, further preferably 810° C. or higher, further preferably 815° C. or higher, further preferably 818° C. or higher, and further preferably 900° C. This makes it possible to reduce the thermal shrinkage of the glass sheet in the LTPS process.

The liquidus temperature is preferably 1370° C. or lower, more preferably lower than 1370° C., further preferably 1360° C. or lower, further preferably 1350° C. or lower, further preferably 1340° C. or lower, further preferably 1330° C. or lower, further preferably 1320° C. or lower, further preferably 1310° C. or lower, further preferably 1300° C. or lower, further preferably 1290° C. or lower, further preferably 1280° C. or lower, further preferably 1270° C. or lower, and particularly preferably 1260° C. or lower. In addition, the liquidus temperature is preferably 1160° C. or higher, more preferably 1170° C. or higher, and particularly preferably 1180° C. or higher. This makes it easy to prevent a situation where devitrified crystals are formed during glass manufacturing to decrease the productivity. Further, the glass sheet can be easily formed by the overflow down-draw method, and thus the surface quality of the glass sheet can be easily improved and the manufacturing cost of the glass sheet can be reduced. Note that the liquidus temperature is an index of the devitrification resistance, and the lower the liquidus temperature is, the better the devitrification resistance is.

The liquidus viscosity is preferably 10^{4.2} dPa·s or more, more preferably 10^{4.3} dPa·s or more, further preferably 10^{4.4} dPa·s or more, and particularly preferably 10^{4.5} dPa·s or more. In addition, the liquidus viscosity is preferably 10^{7.4} dPa·s or less, more preferably 10^{7.2} dPa·s or less, and particularly preferably 10^{7.0} dPa·s or less. With the liquidus viscosity within these ranges, devitrification is less likely to occur during forming, and thus the glass sheet is easily formed by the overflow down-draw method. As a result, the surface quality of the glass sheet can be improved, and the manufacturing cost of the glass sheet can be reduced. Note that the liquidus viscosity is an index of the devitrification resistance and the formability, and the higher the liquidus viscosity is, the higher the devitrification resistance and the formability are.

The temperature at a viscosity in high temperature of 10^{2.5} dPa·s is preferably 1730° C. or lower, more preferably 1720° C. or lower, further preferably 1710° C. or lower, further preferably 1700° C. or lower, further preferably 1690° C. or lower, further preferably 1680° C. or lower, and particularly preferably 1670° C. or lower. In addition, the temperature at a viscosity in high temperature of 10^{2.5} dPa·s is preferably 1580° C. or higher, more preferably 1590° C. or higher, and particularly preferably 1600° C. or higher. When the temperature at a viscosity in high temperature of 10^{2.5} dPa·s is too high, it is difficult to melt the glass batch, and the manufacturing cost of the glass sheet increases. Note that the temperature at a viscosity in high temperature of 10^{2.5} dPa·s corresponds to the melting temperature, and the lower the temperature is, the better the meltability is.

A β-OH value is an index that indicates the amount of water in glass, and, when the β-OH value is decreased, the strain point can be increased. Even when the glass compositions are the same, the smaller the β-OH value is, the smaller the thermal shrinkage ratio at a temperature equal to or lower than the strain point is. The β-OH value is preferably 0.35/mm or less, more preferably 0.30/mm or less, further preferably 0.28/mm or less, further preferably 0.25/mm or less, and particularly preferably 0.20/mm or less. Note that when the β-OH value is too small, the meltability tends to decrease. Thus, the β-OH value is preferably 0.01/mm or more, and particularly preferably 0.03/mm or more.

Examples of a method for decreasing the β-OH value include the following. (1) Selecting a raw material having a low water content. (2) Adding a component (Cl, SO₃ or the like) for decreasing the β-OH value to the glass. (3) Decreasing the amount of water in a furnace atmosphere. (4) Performing N₂ bubbling in molten glass. (5) Adopting a small melting furnace. (6) Increasing a flow rate of the molten glass. (7) Adopting an electric melting method.

Note that the “(β-OH value” refers to a value obtained by substituting the transmittance of the glass measured by using FT-IR according to the following Equation 1.

β-OH value=(1/X)log(T₁/T₂) [Math. 1]
X: sheet thickness (mm)
T₁: transmittance (%) at a reference wavelength of 3846 cm⁻¹
T₂: minimum transmittance (%) near an absorption wavelength of hydroxy groups of 3600 cm⁻¹

The alkali-free glass sheet of the present invention is preferably formed by an overflow down-draw method. The overflow down-draw method is a method for manufacturing a glass sheet by causing molten glass to overflow from both sides of a heat-resistant trough-shaped structure, and drawing and forming the overflowing molten glass downward while joining the overflowing molten glass at a lower end of the trough-shaped structure. In the overflow down-draw method, the surface to be the surface of the glass sheet does not come into contact with the trough-shaped refractory and is formed in a free surface state. Therefore, it is possible to inexpensively manufacture an unpolished glass sheet with good surface quality, and it is also easy to reduce the thickness thereof.

The alkali-free glass sheet of the present invention is also preferably formed by a float method. A large glass sheet can be manufactured at a low cost.

The surface of the alkali-free glass sheet of the present invention is preferably a polished surface. When the glass surface is polished, the total sheet thickness deviation TTV can be reduced. As a result, a magnetic film can be properly formed, which is suitable for a substrate for a magnetic recording medium.

In the alkali-free glass sheet of the present invention, the sheet thickness is not particularly limited, and when the alkali-free glass sheet is used for an organic EL device, the sheet thickness is preferably 0.7 mm or less, more preferably less than 0.7 mm, further preferably 0.6 mm or less, further preferably less than 0.6 mm, and particularly preferably 0.5 mm or less. As the sheet thickness decreases, the weight of the organic EL device can be reduced. The sheet thickness can be adjusted by a flow rate at the time of manufacturing glass, a sheet pulling speed, and the like. Note that, when the alkali-free glass sheet is used for an organic EL device, the sheet thickness is preferably 0.05 mm or more. When the glass sheet is used for a magnetic recording medium, the sheet thickness is preferably 1.5 mm or less, more preferably 1.2 mm or less, further preferably 1.0 mm or less, and particularly preferably 0.9 mm or less. When the glass sheet is used for a magnetic recording medium, the sheet thickness is preferably 0.2 mm or more, and particularly preferably 0.3 mm or more. When the sheet thickness is too large, etching needs to be performed to obtain a desired sheet thickness, and there is a possibility that the processing cost increases.

The alkali-free glass sheet of the present invention is preferably used as a substrate of an organic EL device, particularly, a display panel for an organic EL television, or a carrier for manufacturing an organic EL display panel. Particularly, in the application of an organic EL television, a plurality of devices are produced on a glass sheet, and then the glass sheet is divided and cut for each device to reduce the cost (so-called multiple pattern). Since the alkali-free glass sheet of the present invention can be easily formed into a large glass sheet, such a requirement can be accurately satisfied.

When the alkali-free glass sheet of the present invention is used for an organic EL device, the average surface roughness Ra of the surface is preferably 1.0 nm or less, more preferably 0.5 nm or less, and particularly preferably 0.2 nm or less. When the average surface roughness Ra of the surface is large, in a manufacturing step for a display, it is difficult to accurately pattern the electrodes, etc., and as a result, the probability that circuit electrodes are disconnected or short-circuited increases, making it difficult to ensure the reliability of the display, etc. Here, the “average surface roughness Ra of the surface” refers to the average surface roughness Ra of the main surface (both surfaces) excluding end surfaces, and can be measured using, for example, an atomic force microscope (AFM).

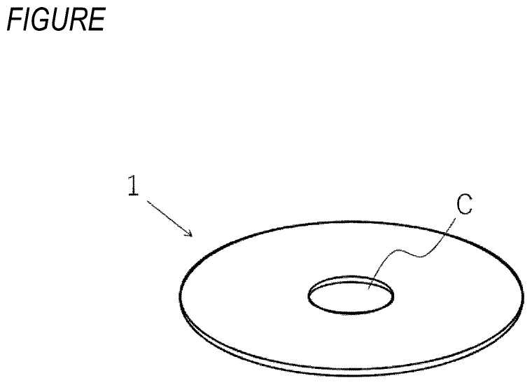

In addition, when the alkali-free glass sheet of the present invention is used as a substrate of a display panel for an organic EL television, or a carrier for manufacturing an organic EL display panel, the shape is preferably rectangular. Further, it is preferable to use the alkali-free glass sheet of the present invention as a substrate for information recording media, particularly an energy assisted magnetic recording medium. Since the degree of ordering (regularity) of the magnetic layer is increased to achieve a high Ku, it can withstand a heat treatment of the base material including the glass substrate at a high temperature of about 800° C. during or before or after the formation of the magnetic layer on the substrate, and the impact to the substrate caused by the high rotation of the magnetic recording medium. The alkali-free glass sheet of the present invention is processed into a disk substrate 1 as illustrated in FIG. 1 by performing processing such as cutting. When the disk substrate 1 is used as a glass substrate for a magnetic recording medium as described above, the disk substrate 1 preferably has a disk shape and further preferably has a circular opening C formed in the center thereof.

### EXAMPLES

Hereinafter, the present invention will be described based on Examples. Note that the following Examples are merely illustrative. The present invention is not limited to the following Examples in any way.

Tables 1 to 5 list Examples (Sample Nos. 1 to 48) of the present invention.

TABLE 1

| | | No. 1 | No. 2 | No. 3 | No. 4 | No. 5 | No. 6 | No. 7 | No. 8 | No. 9 | No. 10 |
|---|---|---|---|---|---|---|---|---|---|---|---|
| Glass | SiO₂ | 70.9 | 70.9 | 70.9 | 70.9 | 70.9 | 70.9 | 70.9 | 70.9 | 71.9 | 71.9 |
| composition | Al₂O₃ | 13.0 | 13.0 | 13.0 | 13.0 | 13.0 | 13.0 | 13.0 | 13.0 | 13.0 | 13.0 |
| (mol %) | B₂O₃ | 0.0 | 0.0 | 0.0 | 0.0 | 0.0 | 0.0 | 0.0 | 0.0 | 0.0 | 0.0 |
| | Li₂O | 0.00 | 0.00 | 0.00 | 0.00 | 0.00 | 0.00 | 0.00 | 0.00 | 0.00 | 0.00 |
| | Na₂O | 0.01 | 0.01 | 0.01 | 0.01 | 0.02 | 0.01 | 0.01 | 0.01 | 0.01 | 0.01 |
| | K₂O | 0.002 | 0.001 | 0.001 | 0.002 | 0.001 | 0.001 | 0.001 | 0.002 | 0.001 | 0.002 |
| | MgO | 8.0 | 8.0 | 8.0 | 6.0 | 6.0 | 6.0 | 6.0 | 4.0 | 7.5 | 7.5 |
| | CaO | 8.0 | 6.0 | 4.0 | 10.0 | 8.0 | 6.0 | 4.0 | 8.0 | 7.5 | 5.5 |
| | SrO | 0.01 | 1.0 | 2.0 | 0.01 | 1.0 | 2.0 | 3.0 | 2.0 | 0.01 | 1.0 |
| | BaO | 0.01 | 1.0 | 2.0 | 0.01 | 1.0 | 2.0 | 3.0 | 2.0 | 0.01 | 1.0 |
| | ZnO | 0.001 | 0.001 | 0.001 | 0.001 | 0.001 | 0.001 | 0.001 | 0.001 | 0.001 | 0.001 |
| | SnO₂ | 0.09 | 0.09 | 0.09 | 0.09 | 0.09 | 0.09 | 0.09 | 0.09 | 0.09 | 0.09 |
| | Fe₂O₃ | 0.008 | 0.008 | 0.008 | 0.008 | 0.007 | 0.007 | 0.006 | 0.006 | 0.008 | 0.007 |
| | TiO₂ | 0.010 | 0.008 | 0.008 | 0.008 | 0.007 | 0.008 | 0.007 | 0.001 | 0.006 | 0.007 |
| | ZrO₂ | 0.001 | 0.001 | 0.001 | 0.001 | 0.001 | 0.001 | 0.001 | 0.001 | 0.001 | 0.001 |

| | | | | | | | | | | |
|---|---|---|---|---|---|---|---|---|---|---|
| Li₂O + Na₂O + K₂O | 0.012 | 0.012 | 0.012 | 0.012 | 0.023 | 0.012 | 0.012 | 0.013 | 0.012 | 0.013 |
| MgO + CaO + SrO + BaO | 16.0 | 16.0 | 16.0 | 16.0 | 16.0 | 16.0 | 16.0 | 16.0 | 15.0 | 15.0 |
| Al₂O₃/ | 0.81 | 0.81 | 0.81 | 0.81 | 0.81 | 0.81 | 0.81 | 0.81 | 0.87 | 0.87 |
| (MgO + CaO + SrO + BaO) | | | | | | | | | | |
| SrO/BaO | 1.00 | 1.00 | 1.00 | 1.00 | 1.00 | 1.00 | 1.00 | 1.00 | 1.00 | 1.00 |
| SiO₂/Al₂O₃ | 5.45 | 5.45 | 5.45 | 5.45 | 5.45 | 5.45 | 5.45 | 5.45 | 5.53 | 5.53 |
| (MgO + CaO + SrO + | 3.0 | 3.0 | 3.0 | 3.0 | 3.0 | 3.0 | 3.0 | 3.0 | 2.0 | 2.0 |
| BaO)—Al₂O₃ | | | | | | | | | | |
| (MgO + CaO)/(SrO + BaO) | 800.0 | 7.0 | 3.0 | 800.0 | 7.0 | 3.0 | 1.7 | 3.0 | 750.0 | 6.5 |
| MgO/CaO | 1.0 | 1.3 | 2.0 | 0.6 | 0.8 | 1.0 | 1.5 | 0.5 | 1.0 | 1.4 |
| (Al₂O₃ + MgO)/ | 1050.0 | 10.5 | 5.3 | 950.0 | 9.5 | 4.8 | 3.2 | 4.3 | 1025.0 | 10.3 |
| (B₂O₃ + SrO + BaO) | | | | | | | | | | |
| SiO₂/(Al₂O₃—B₂O₃) | 5.45 | 5.45 | 5.45 | 5.45 | 5.45 | 5.45 | 5.45 | 5.45 | 5.53 | 5.53 |
| CTE [×10⁻⁷/° C.] | 34.2 | 34.6 | 36 | 36 | 36.6 | 37.4 | 38.0 | 38.7 | 33.2 | 34.0 |
| ρ [g/cm³] | 2.49 | 2.53 | 2.58 | 2.50 | 2.54 | 2.58 | 2.63 | 2.59 | 2.48 | 2.52 |
| E [GPa] | 88 | 87 | 86 | 87 | 86 | 85 | 84 | 84 | 88 | 87 |
| Ps [° C.] | 761 | 763 | 761 | 766 | 763 | 760 | 762 | 764 | 768 | 766 |
| Ta [° C.] | 818 | 820 | 820 | 822 | 820 | 820 | 822 | 823 | 825 | 824 |
| Ts [° C.] | 1045 | 1043 | 1050 | 1050 | 1048 | 1051 | 1057 | 1055 | 1053 | 1056 |
| 10⁴ dPa · s[° C.] | 1348 | 1362 | 1364 | 1355 | 1363 | 1371 | 1381 | 1374 | 1369 | 1379 |
| 10³ dPa · s[° C.] | 1508 | 1521 | 1524 | 1514 | 1523 | 1533 | 1544 | 1537 | 1531 | 1540 |
| 10^{2.5} dPa · s[° C.] | 1607 | 1622 | 1625 | 1615 | 1626 | 1636 | 1649 | 1643 | 1633 | 1644 |
| TL [° C.] | 1291 | 1289 | 1298 | 1292 | 1259 | 1250 | 1251 | 1298 | 1329 | 1307 |
| Log₁₀ ηTL | 4.5 | 4.6 | 4.6 | 4.5 | 4.9 | 5.1 | 5.1 | 4.6 | 4.3 | 4.6 |

TABLE 2

| | | No. 11 | No. 12 | No. 13 | No. 14 | No. 15 | No. 16 | No. 17 | No. 18 | No. 19 | No. 20 |
|---|---|---|---|---|---|---|---|---|---|---|---|
| Glass | SiO₂ | 71.9 | 71.9 | 71.9 | 71.9 | 71.9 | 71.9 | 72.9 | 72.9 | 72.9 | 72.9 |
| composition | Al₂O₃ | 13.0 | 13.0 | 13.0 | 13.0 | 13.0 | 13.0 | 13.0 | 13.0 | 13.0 | 13.0 |
| (mol %) | B₂O₃ | 0.0 | 0.0 | 0.0 | 0.0 | 0.0 | 0.0 | 0.0 | 0.0 | 0.0 | 0.0 |
| | Li₂O | 0.00 | 0.00 | 0.00 | 0.00 | 0.00 | 0.00 | 0.00 | 0.00 | 0.00 | 0.00 |
| | Na₂O | 0.01 | 0.01 | 0.01 | 0.01 | 0.01 | 0.01 | 0.01 | 0.01 | 0.01 | 0.01 |
| | K₂O | 0.001 | 0.001 | 0.001 | 0.002 | 0.001 | 0.002 | 0.006 | 0.004 | 0.003 | 0.003 |
| | MgO | 7.5 | 5.5 | 5.5 | 5.5 | 5.5 | 3.5 | 7.0 | 7.0 | 5.0 | 5.0 |
| | CaO | 3.5 | 9.5 | 7.5 | 5.5 | 3.5 | 7.5 | 5.0 | 3.0 | 7.0 | 5.0 |
| | SrO | 2.0 | 0.01 | 1.0 | 2.0 | 3.0 | 2.0 | 1.0 | 2.0 | 1.0 | 2.0 |
| | BaO | 2.0 | 0.01 | 1.0 | 2.0 | 3.0 | 2.0 | 1.0 | 2.0 | 1.0 | 2.0 |
| | ZnO | 0.001 | 0.001 | 0.001 | 0.000 | 0.001 | 0.001 | 0.001 | 0.001 | 0.001 | 0.000 |
| | SnO₂ | 0.09 | 0.09 | 0.09 | 0.09 | 0.09 | 0.09 | 0.09 | 0.09 | 0.09 | 0.09 |
| | Fe₂O₃ | 0.007 | 0.007 | 0.007 | 0.007 | 0.006 | 0.006 | 0.007 | 0.007 | 0.007 | 0.007 |
| | TiO₂ | 0.007 | 0.006 | 0.007 | 0.008 | 0.008 | 0.007 | 0.012 | 0.013 | 0.007 | 0.008 |
| | ZrO₂ | 0.001 | 0.001 | 0.001 | 0.001 | 0.001 | 0.001 | 0.002 | 0.001 | 0.001 | 0.001 |

| | | | | | | | | | | |
|---|---|---|---|---|---|---|---|---|---|---|
| Li₂O + Na₂O + K₂O | 0.012 | 0.012 | 0.012 | 0.013 | 0.013 | 0.013 | 0.016 | 0.014 | 0.013 | 0.014 |
| MgO + CaO + SrO + BaO | 15.0 | 15.0 | 15.0 | 15.0 | 15.0 | 15.0 | 14.0 | 14.0 | 14.0 | 14.0 |
| Al₂O₃/ | 0.87 | 0.87 | 0.87 | 0.87 | 0.87 | 0.87 | 0.93 | 0.93 | 0.93 | 0.93 |
| (MgO + CaO + SrO + BaO) | | | | | | | | | | |
| SrO/BaO | 1.00 | 1.00 | 1.00 | 1.00 | 1.00 | 1.00 | 1.00 | 1.00 | 1.00 | 1.00 |
| SiO₂/A₁₂O₃ | 5.53 | 5.53 | 5.53 | 5.53 | 5.53 | 5.53 | 5.61 | 5.61 | 5.61 | 5.61 |
| (MgO + CaO + SrO + | 2.0 | 2.0 | 2.0 | 2.0 | 2.0 | 2.0 | 1.0 | 1.0 | 1.0 | 1.0 |
| BaO)—Al₂O₃ | | | | | | | | | | |
| (MgO + CaO)/(SrO + BaO) | 2.8 | 750.0 | 6.5 | 2.8 | 1.5 | 2.8 | 6.0 | 2.5 | 6.0 | 2.5 |
| MgO/CaO | 2.1 | 0.6 | 0.7 | 1.0 | 1.6 | 0.5 | 1.4 | 2.3 | 0.7 | 1.0 |
| (Al₂O₃ + MgO)/ | 5.1 | 925.0 | 9.3 | 4.6 | 3.1 | 4.1 | 10.0 | 5.0 | 9.0 | 4.5 |
| (B₂O₃ + SrO + BaO) | | | | | | | | | | |
| SiO₂/(Al₂O₃—B₂O₃) | 5.53 | 5.53 | 5.53 | 5.53 | 5.53 | 5.53 | 5.61 | 5.61 | 5.61 | 5.61 |
| CTE [×10⁻⁷/° C.] | 34.6 | 34.7 | 35 | 35.7 | 37.5 | 37.8 | 32.4 | 33.1 | 33.9 | 34.6 |
| ρ [g/cm³] | 2.57 | 2.49 | 2.53 | 2.57 | 2.62 | 2.58 | 2.51 | 2.55 | 2.52 | 2.56 |
| E [GPa] | 86 | 87 | 86 | 85 | 84 | 84 | 86 | 85 | 86 | 85 |
| Ps [° C.] | 765 | 771 | 768 | 767 | 765 | 770 | 768 | 770 | 773 | 771 |
| Ta [° C.] | 825 | 828 | 827 | 826 | 826 | 830 | 829 | 830 | 833 | 832 |
| Ts [° C.] | 1060 | 1055 | 1058 | 1063 | 1065 | 1067 | 1066 | 1071 | 1070 | 1074 |
| 10⁴ dPa · s[° C.] | 1386 | 1374 | 1381 | 1392 | 1398 | 1394 | 1391 | 1399 | 1396 | 1405 |
| 10³ dPa · s[° C.] | 1549 | 1534 | 1545 | 1556 | 1564 | 1557 | 1555 | 1564 | 1560 | 1570 |
| 10^{2.5} dPa · s[° C.] | 1652 | 1637 | 1646 | 1663 | 1670 | 1659 | 1661 | 1671 | 1668 | 1676 |
| TL [° C.] | 1315 | 1318 | 1276 | 1251 | 1254 | 1290 | 1322 | 1312 | 1296 | 1257 |
| Log₁₀ ηTL | 4.6 | 4.5 | 4.9 | 5.2 | 5.2 | 4.9 | 4.6 | 4.7 | 4.8 | 5.3 |

TABLE 3

| | | No. 21 | No. 22 | No. 23 | No. 24 | No. 25 | No. 26 | No. 27 | No. 28 | No. 29 | No. 30 |
|---|---|---|---|---|---|---|---|---|---|---|---|
| Glass | SiO₂ | 72.9 | 73.9 | 73.9 | 73.9 | 73.9 | 73.9 | 70.9 | 70.9 | 70.9 | 71.9 |
| composition | Al₂O₃ | 13.0 | 13.0 | 13.0 | 13.0 | 13.0 | 13.0 | 13.5 | 13.5 | 13.5 | 13.5 |
| (mol %) | B₂O₃ | 0.0 | 0.0 | 0.0 | 0.0 | 0.0 | 0.0 | 0.0 | 0.0 | 0.0 | 0.0 |
| | Li₂O | 0.00 | 0.00 | 0.00 | 0.00 | 0.00 | 0.00 | 0.00 | 0.00 | 0.00 | 0.00 |
| | Na₂O | 0.02 | 0.02 | 0.01 | 0.01 | 0.01 | 0.01 | 0.01 | 0.01 | 0.01 | 0.01 |
| | K₂O | 0.001 | 0.002 | 0.002 | 0.002 | 0.001 | 0.002 | 0.001 | 0.002 | 0.002 | 0.003 |
| | MgO | 5.0 | 6.5 | 6.5 | 4.5 | 4.5 | 4.5 | 5.5 | 6.0 | 6.0 | 5.0 |
| | CaO | 3.0 | 4.5 | 2.5 | 6.5 | 4.5 | 2.5 | 6.0 | 6.0 | 6.0 | 5.5 |
| | SrO | 3.0 | 1.0 | 2.0 | 1.0 | 2.0 | 3.0 | 2.0 | 1.5 | 2.0 | 2.0 |
| | BaO | 3.0 | 1.0 | 2.0 | 1.0 | 2.0 | 3.0 | 2.0 | 2.0 | 1.5 | 2.0 |
| | ZnO | 0.001 | 0.001 | 0.001 | 0.001 | 0.001 | 0.001 | 0.001 | 0.001 | 0.001 | 0.001 |
| | SnO₂ | 0.09 | 0.09 | 0.09 | 0.09 | 0.09 | 0.09 | 0.09 | 0.09 | 0.09 | 0.09 |
| | Fe₂O₃ | 0.006 | 0.007 | 0.007 | 0.007 | 0.006 | 0.006 | 0.007 | 0.007 | 0.071 | 0.007 |
| | TiO₂ | 0.008 | 0.007 | 0.008 | 0.007 | 0.008 | 0.008 | 0.007 | 0.008 | 0.008 | 0.008 |
| | ZrO₂ | 0.001 | 0.001 | 0.001 | 0.001 | 0.001 | 0.001 | 0.001 | 0.001 | 0.001 | 0.001 |

| | | | | | | | | | | |
|---|---|---|---|---|---|---|---|---|---|---|
| Li₂O + Na₂O + K₂O | 0.024 | 0.023 | 0.013 | 0.013 | 0.012 | 0.013 | 0.012 | 0.013 | 0.013 | 0.014 |
| MgO + CaO + SrO + BaO | 14.0 | 13.0 | 13.0 | 13.0 | 13.0 | 13.0 | 15.5 | 15.5 | 15.5 | 14.5 |
| Al₂O₃/ | 0.93 | 1.00 | 1.00 | 1.00 | 1.00 | 1.00 | 0.87 | 0.87 | 0.87 | 0.93 |
| (MgO + CaO + SrO + BaO) | | | | | | | | | | |
| SrO/BaO | 1.00 | 1.00 | 1.00 | 1.00 | 1.00 | 1.00 | 1.00 | 0.75 | 1.33 | 1.00 |
| SiO₂/Al₂O₃ | 5.61 | 5.69 | 5.69 | 5.69 | 5.69 | 5.69 | 5.25 | 5.25 | 5.25 | 5.33 |
| (MgO + CaO + SrO + | 1.0 | 0.0 | 0.0 | 0.0 | 0.0 | 0.0 | 2.0 | 2.0 | 2.0 | 1.0 |
| BaO)—Al₂O₃ | | | | | | | | | | |
| (MgO + CaO)/(SrO + BaO) | 1.3 | 5.5 | 2.3 | 5.5 | 2.3 | 1.2 | 2.9 | 3.4 | 3.4 | 2.6 |
| MgO/CaO | 1.7 | 1.4 | 2.6 | 0.7 | 1.0 | 1.8 | 0.9 | 1.0 | 1.0 | 0.9 |
| (Al₂O₃ + MgO)/ | 3.0 | 9.8 | 4.9 | 8.8 | 4.4 | 2.9 | 4.8 | 5.6 | 5.6 | 4.6 |
| (B₂O₃ + SrO + BaO) | | | | | | | | | | |
| SiO₂/(Al₂O₃—B₂O₃) | 5.61 | 5.69 | 5.69 | 5.69 | 5.69 | 5.69 | 5.25 | 5.25 | 5.25 | 5.33 |
| CTE [×10⁻⁷/° C.] | 35.6 | 31 | 31.8 | 32.7 | 33.4 | 34.3 | 36.6 | 36.0 | 36.0 | 35.4 |
| ρ [g/cm³] | 2.60 | 2.50 | 2.54 | 2.50 | 2.55 | 2.59 | 2.58 | 2.57 | 2.57 | 2.57 |
| E [GPa] | 84 | 86 | 85 | 85 | 84 | 83 | 86 | 86 | 86 | 85 |
| Ps [° C.] | 773 | 775 | 775 | 777 | 777 | 779 | 766 | 766 | 766 | 771 |
| Ta [° C.] | 835 | 835 | 837 | 839 | 840 | 842 | 826 | 824 | 824 | 831 |
| Ts [° C.] | 1081 | 1076 | 1082 | 1081 | 1085 | 1092 | 1057 | 1055 | 1056 | 1068 |
| 10⁴ dPa · s[° C.] | 1416 | 1403 | 1411 | 1412 | 1426 | 1435 | 1377 | 1372 | 1372 | 1392 |
| 10³ dPa · s[° C.] | 1584 | 1568 | 1578 | 1578 | 1594 | 1604 | 1538 | 1532 | 1533 | 1556 |
| 10^{2.5} dPa · s[° C.] | 1695 | 1675 | 1688 | 1686 | 1702 | 1711 | 1640 | 1634 | 1636 | 1661 |
| TL [° C.] | 1274 | 1365 | 1359 | 1323 | 1311 | 1300 | 1245 | 1270 | 1266 | 1275 |
| Log₁₀ ηTL | 5.2 | 4.3 | 4.4 | 4.7 | 4.9 | 5.1 | 5.2 | 4.9 | 4.9 | 5.0 |

TABLE 4

| | | No. 31 | No. 32 | No. 33 | No. 34 | No. 35 | No. 36 | No. 37 | No. 38 | No. 39 | No. 40 |
|---|---|---|---|---|---|---|---|---|---|---|---|
| Glass | SiO₂ | 71.9 | 71.9 | 72.9 | 73.9 | 71.9 | 71.9 | 71.9 | 72.9 | 72.9 | 73.9 |
| composition | Al₂O₃ | 13.5 | 13.5 | 13.0 | 13.0 | 13.0 | 13.0 | 13.0 | 13.0 | 13.0 | 13.0 |
| (mol %) | B₂O₃ | 0.0 | 0.0 | 0.0 | 0.0 | 0.0 | 1.0 | 1.0 | 1.0 | 1.0 | 1.0 |
| | Li₂O | 0.00 | 0.00 | 0.00 | 0.00 | 0.00 | 0.00 | 0.00 | 0.00 | 0.00 | 0.00 |
| | Na₂O | 0.01 | 0.01 | 0.01 | 0.01 | 0.01 | 0.01 | 0.02 | 0.01 | 0.01 | 0.01 |
| | K₂O | 0.001 | 0.003 | 0.003 | 0.003 | 0.002 | 0.002 | 0.002 | 0.003 | 0.001 | 0.002 |
| | MgO | 5.5 | 5.5 | 3.0 | 2.5 | 4.5 | 4.5 | 5.0 | 4.0 | 4.5 | 3.5 |
| | CaO | 5.5 | 5.5 | 7.0 | 6.5 | 6.5 | 5.5 | 5.0 | 5.0 | 4.5 | 4.5 |
| | SrO | 1.5 | 1.0 | 2.0 | 2.0 | 2.0 | 2.0 | 2.0 | 2.0 | 2.0 | 2.0 |
| | BaO | 2.0 | 2.5 | 2.0 | 2.0 | 2.0 | 2.0 | 2.0 | 2.0 | 2.0 | 2.0 |
| | ZnO | 0.001 | 0.001 | 0.001 | 0.001 | 0.001 | 0.000 | 0.000 | 0.001 | 0.001 | 0.001 |
| | SnO₂ | 0.09 | 0.09 | 0.09 | 0.09 | 0.09 | 0.09 | 0.09 | 0.09 | 0.09 | 0.09 |
| | Fe₂O₃ | 0.007 | 0.007 | 0.007 | 0.007 | 0.008 | 0.007 | 0.007 | 0.007 | 0.006 | 0.006 |
| | TiO₂ | 0.008 | 0.008 | 0.008 | 0.008 | 0.008 | 0.008 | 0.008 | 0.008 | 0.008 | 0.008 |
| | ZrO₂ | 0.001 | 0.001 | 0.002 | 0.001 | 0.001 | 0.001 | 0.001 | 0.001 | 0.001 | 0.001 |

| | | | | | | | | | | |
|---|---|---|---|---|---|---|---|---|---|---|
| Li₂O + Na₂O + K₂O | 0.012 | 0.014 | 0.014 | 0.014 | 0.013 | 0.013 | 0.024 | 0.014 | 0.012 | 0.013 |
| MgO + CaO + SrO + BaO | 14.5 | 14.5 | 14.0 | 13.0 | 15.0 | 14.0 | 14.0 | 13.0 | 13.0 | 12.0 |
| Al₂O₃/ | 0.93 | 0.93 | 0.93 | 1.00 | 0.87 | 0.93 | 0.93 | 1.00 | 1.00 | 1.08 |
| (MgO + CaO + SrO + BaO) | | | | | | | | | | |
| SrO/BaO | 0.75 | 0.40 | 1.00 | 1.00 | 1.00 | 1.00 | 1.00 | 1.00 | 1.00 | 1.00 |
| SiO₂/Al₂O₃ | 5.33 | 5.33 | 5.61 | 5.69 | 5.53 | 5.53 | 5.53 | 5.61 | 5.61 | 5.69 |
| (MgO + CaO + SrO + | 1.0 | 1.0 | 1.0 | 0.0 | 2.0 | 1.0 | 1.0 | 0.0 | 0.0 | −1.0 |
| BaO)—Al₂O₃ | | | | | | | | | | |
| (MgO + CaO)/(SrO + BaO) | 3.1 | 3.1 | 2.5 | 2.3 | 2.8 | 2.5 | 2.5 | 2.3 | 2.3 | 2.0 |
| MgO/CaO | 1.0 | 1.0 | 0.4 | 0.4 | 0.7 | 0.8 | 1.0 | 0.8 | 1.0 | 0.8 |
| (Al₂O₃ + MgO)/ | 5.4 | 5.4 | 4.0 | 3.9 | 4.4 | 3.5 | 3.6 | 3.4 | 3.5 | 3.3 |
| (B₂O₃ + SrO + BaO) | | | | | | | | | | |
| SiO₂/(Al₂O₃—B₂O₃) | 5.33 | 5.33 | 5.61 | 5.69 | 5.53 | 5.99 | 5.99 | 6.08 | 6.08 | 6.16 |
| CTE [×10⁻⁷/° C.] | 34.7 | 34.7 | 36.4 | 35 | 36.9 | 35.1 | 34.7 | 33.9 | 33.5 | 32.8 |
| ρ [g/cm³] | 2.56 | 2.57 | 2.56 | 2.55 | 2.57 | 2.55 | 2.55 | 2.54 | 2.54 | 2.53 |
| E [GPa] | 86 | 85 | 84 | 83 | 84 | 83 | 84 | 83 | 83 | 82 |
| Ps [° C.] | 771 | 770 | 778 | 784 | 769 | 760 | 760 | 764 | 764 | 768 |
| Ta [° C.] | 831 | 831 | 839 | 847 | 829 | 819 | 819 | 825 | 825 | 830 |
| Ts [° C.] | 1066 | 1066 | 1079 | 1091 | 1065 | 1059 | 1059 | 1069 | 1069 | 1078 |
| 10⁴ dPa · s[° C.] | 1389 | 1392 | 1405 | 1425 | 1385 | 1393 | 1392 | 1409 | 1408 | 1425 |
| 10³ dPa · s[° C.] | 1552 | 1555 | 1572 | 1593 | 1550 | 1559 | 1558 | 1577 | 1576 | 1596 |
| 10^{2.5} dPa · s[° C.] | 1657 | 1659 | 1678 | 1700 | 1658 | 1667 | 1665 | 1687 | 1685 | 1707 |
| TL [° C.] | 1270 | 1277 | 1281 | 1286 | 1261 | 1234 | 1250 | 1277 | 1291 | 1340 |
| Log₁₀ ηTL | 5.0 | 5.0 | 5.1 | 5.2 | 5.1 | 5.4 | 5.2 | 5.1 | 5.0 | 4.7 |

TABLE 5

| | | No. 41 | No. 42 | No. 43 | No. 44 | No. 45 | No. 46 | No. 47 | No. 48 |
|---|---|---|---|---|---|---|---|---|---|
| Glass | SiO₂ | 71.2 | 71.2 | 70.8 | 71.3 | 71.8 | 72.8 | 72.8 | 71.3 |
| composition | Al₂O₃ | 13.0 | 13.5 | 13.5 | 13.2 | 13.0 | 13.0 | 13.0 | 13.5 |
| (mol %) | B₂O₃ | 0.6 | 1.1 | 1.0 | 0.0 | 0.0 | 1.0 | 0.0 | 0.0 |
| | Li₂O | 0.00 | 0.00 | 0.00 | 0.00 | 0.00 | 0.00 | 0.00 | 0.00 |
| | Na₂O | 0.03 | 0.02 | 0.01 | 0.01 | 0.01 | 0.01 | 0.02 | 0.01 |
| | K₂O | 0.004 | 0.003 | 0.002 | 0.003 | 0.002 | 0.002 | 0.003 | 0.002 |
| | MgO | 5.3 | 4.6 | 4.6 | 5.6 | 5.1 | 3.1 | 4.1 | 5.3 |
| | CaO | 5.7 | 5.5 | 6.0 | 5.8 | 6.0 | 6.0 | 6.0 | 5.8 |
| | SrO | 2.0 | 2.0 | 2.0 | 2.0 | 2.0 | 2.0 | 2.0 | 2.0 |
| | BaO | 2.0 | 2.0 | 2.0 | 2.0 | 2.0 | 2.0 | 2.0 | 2.0 |
| | ZnO | 0.001 | 0.001 | 0.001 | 0.001 | 0.001 | 0.001 | 0.001 | 0.000 |
| | SnO₂ | 0.08 | 0.09 | 0.08 | 0.08 | 0.08 | 0.09 | 0.08 | 0.09 |
| | Fe₂O₃ | 0.005 | 0.005 | 0.005 | 0.005 | 0.005 | 0.006 | 0.005 | 0.005 |
| | TiO₂ | 0.007 | 0.007 | 0.008 | 0.008 | 0.007 | 0.008 | 0.007 | 0.008 |
| | ZrO₂ | 0.001 | 0.001 | 0.001 | 0.001 | 0.001 | 0.001 | 0.001 | 0.001 |

| | | | | | | | | |
|---|---|---|---|---|---|---|---|---|
| Li₂O + Na₂O + K₂O | 0.037 | 0.025 | 0.013 | 0.014 | 0.013 | 0.013 | 0.025 | 0.013 |
| MgO + CaO + SrO + BaO | 15.0 | 14.1 | 14.6 | 15.4 | 15.1 | 13.1 | 14.1 | 15.1 |
| Al₂O₃/(MgO + CaO + SrO + BaO) | 0.87 | 0.96 | 0.93 | 0.86 | 0.86 | 0.99 | 0.92 | 0.89 |
| SrO/BaO | 1.00 | 1.00 | 1.00 | 1.00 | 1.01 | 1.00 | 1.00 | 0.98 |
| SiO₂/Al₂O₃ | 5.47 | 5.27 | 5.24 | 5.39 | 5.51 | 5.59 | 5.59 | 5.30 |
| (MgO + CaO + SrO + BaO)—Al₂O₃ | 2.0 | 0.6 | 1.0 | 2.1 | 2.0 | 0.1 | 1.1 | 1.6 |
| (MgO + CaO)/(SrO + BaO) | 2.8 | 2.5 | 2.6 | 2.8 | 2.8 | 2.3 | 2.5 | 2.8 |
| MgO/CaO | 0.9 | 0.8 | 0.8 | 1.0 | 0.8 | 0.5 | 0.7 | 0.9 |
| (Al₂O₃ + MgO)/(B₂O₃ + SrO + BaO) | 4.0 | 3.6 | 3.6 | 4.7 | 4.5 | 3.2 | 4.2 | 4.8 |
| SiO₂/(Al₂O₃—B₂O₃) | 5.72 | 5.73 | 5.65 | 5.39 | 5.51 | 6.04 | 5.59 | 5.30 |
| CTE [×10⁻⁷/° C.] | 35.9 | 34.8 | 35.8 | 36.3 | 36.2 | 34.6 | 35.4 | 36.0 |
| ρ [g/cm³] | 2.57 | 2.56 | 2.57 | 2.58 | 2.57 | 2.55 | 2.56 | 2.58 |
| E [GPa] | 85 | 84 | 84 | 85 | 85 | 82 | 84 | 85 |
| Ps [° C.] | 761 | 761 | 759 | 768 | 769 | 766 | 776 | 770 |
| Ta [° C.] | 819 | 820 | 818 | 826 | 827 | 827 | 836 | 829 |
| Ts [° C.] | 1056 | 1058 | 1054 | 1059 | 1064 | 1073 | 1076 | 1062 |
| 10⁴ dPa · s[° C.] | 1380 | 1382 | 1376 | 1380 | 1389 | 1409 | 1409 | 1382 |
| 10³ dPa · s[° C.] | 1546 | 1545 | 1538 | 1542 | 1552 | 1576 | 1574 | 1544 |
| 10^{2.5} dPa · s[° C.] | 1656 | 1649 | 1642 | 1644 | 1656 | 1684 | 1683 | 1648 |
| TL [° C.] | 1243 | 1267 | 1240 | 1249 | 1240 | 1254 | 1250 | 1242 |
| Log₁₀ ηTL | 5.2 | 5.0 | 5.2 | 5.1 | 5.3 | 5.3 | 5.4 | 5.2 |

First, glass raw materials were mixed to give a glass composition presented in the tables, and the glass batch was charged into a platinum crucible and melted at a temperature of from 1600° C. to 1680° C. for 24 hours. At the time of melting, the glass batch was homogenized by stirring with a platinum stirrer. Next, the molten glass was poured onto a carbon sheet, formed into a sheet shape, and then gradually cooled at a temperature near the annealing point for 30 minutes. Each of the obtained samples was evaluated for the average thermal expansion coefficient CTE in a temperature range of from 30° C. to 380° C., the density ρ, the Young's modulus E, the strain point Ps, the annealing point Ta, the softening point Ts, the temperature at a viscosity in high temperature of 10⁴ dPa·s, the temperature at a viscosity in high temperature of 10³ dPa·s, the temperature at a viscosity in high temperature of 10^{2.5} dPa·s, the liquidus temperature TL, and the viscosity log₁₀ ηTL at the liquidus temperature TL.

The average thermal expansion coefficient CTE in a temperature range of from 30° C. to 380° C. is a value measured with a dilatometer.

The density ρ is a value measured using the well-known Archimedes method.

The Young's modulus E refers to a value measured by a well-known resonance method.

The strain point Ps, the annealing point Ta, and the softening point Ts are values measured based on methods in ASTM C336 and C338.

The temperatures at a viscosity in high temperature of 10⁴ dPa·s, 10³ dPa·s, and 10^{2.5} dPa·s are values measured by a platinum sphere pull up method.

The liquidus temperature TL is a temperature at which crystals precipitate after a glass powder that has passed through a standard 30-mesh sieve (500 μm) and remained on a 50-mesh sieve (300 μm) is charged into a platinum boat and then kept in a temperature gradient furnace for 24 hours.

The liquidus viscosity log₁₀ ηTL is a value obtained by measuring the viscosity of glass at the liquidus temperature TL by a platinum sphere pull up method.

As is clear from Tables 1 to 5, in Sample Nos. 1 to 48, since the glass composition is regulated within a predetermined range, the Young's modulus is 82 GPa or more, the strain point is 759° C. or higher, the liquidus temperature is 1365° C. or lower, and the liquidus viscosity is 10^{4.3} dPa·s or more. Therefore, Sample Nos. 1 to 48 are excellent in productivity and sufficiently high in strain point and Young's modulus, and are thus suitable for substrates of organic EL devices.

### INDUSTRIAL APPLICABILITY

The alkali-free glass sheet of the present invention is suitable as a substrate of a display panel for an organic EL device, particularly, an organic EL television, or a carrier for manufacturing an organic EL display panel, and is also suitable as a substrate of a flat panel display such as a liquid crystal display, cover glass for an image sensor such as a charge-coupled device (CCD) or an equal-magnification proximity solid-state imaging device (CIS), a substrate and cover glass for a solar cell, or a substrate for an organic EL illumination.

In addition, the alkali-free glass sheet of the present invention is also suitable as a glass substrate for a magnetic recording medium.

### REFERENCE SIGNS LIST

1 disk substrate

1: An alkali-free glass sheet comprising, as a glass composition, in mol %, from 69% to 76% of SiO₂, from 12% to 15% of Al₂O₃, from 0% to 2% of B₂O₃, from 0% to 0.5% of Li₂O+Na₂O+K₂O, from 2% to 10% of MgO, from 2% to 12% of CaO, more than 0% to 5% of SrO, more than 0% to 5% of BaO, and from 12% to 18% of MgO+CaO+SrO+BaO, wherein a mol % ratio Al₂O₃/(MgO+CaO+SrO+BaO) is from 0.5 to 1.5, and a mol % ratio SrO/BaO is from 0.3 to 1.6.

2: The alkali-free glass sheet according to claim 1, comprising, as a glass composition, in mol %, from 70% to 75% of SiO₂, from 13% to 14% of Al₂O₃, from 0% to 1% of B₂O₃, from 0% to 0.1% of Li₂O+Na₂O+K₂O, from 2% to 9% of MgO, from 2% to 11% of CaO, more than 0% to 4% of SrO, more than 0% to 4% of BaO, and from 13% to 17% of MgO+CaO+SrO+BaO, wherein the mol % ratio Al₂O₃/(MgO+CaO+SrO+BaO) is from 0.8 to 1.2, and the mol % ratio SrO/BaO is from 0.6 to 1.5.

3: The alkali-free glass sheet according to claim 1, comprising, as a glass composition, in mol %, from 69% to 76% of SiO₂, from 12.6% to 15% of Al₂O₃, from 0% to 1% of B₂O₃, from 0% to 0.5% of Li₂O+Na₂O+K₂O, from 2% to 10% of MgO, from 2% to 12% of CaO, more than 0% to 5% of SrO, more than 0% to 5% of BaO, from 0% to 0.2% of ZnO, and from 12% to 18% of MgO+CaO+SrO+BaO, wherein the mol % ratio Al₂O₃/(MgO+CaO+SrO+BaO) is from 0.5 to 1.5, the mol % ratio SrO/BaO is from 0.6 to 1.6, and MgO+CaO+SrO+BaO—Al₂O₃ is from −1.5% to 4%.

4: The alkali-free glass sheet according to claim 3, comprising, as a glass composition, in mol %, from 70% to 76% of SiO₂, from 13% to 15% of Al₂O₃, from 0% to 1% of B₂O₃, from 0% to 0.5% of Li₂O+Na₂O+K₂O, from 2% to 10% of MgO, from 2% to 12% of CaO, more than 0% to 5% of SrO, more than 0% to 5% of BaO, from 0% to 0.2% of ZnO, and from 12% to 18% of MgO+CaO+SrO+BaO, wherein the mol % ratio Al₂O₃/(MgO+CaO+SrO+BaO) is from 0.5 to 1.5, the mol % ratio SrO/BaO is from 0.6 to 1.6, and MgO+CaO+SrO+BaO—Al₂O₃ is from −1.5% to 4%.

5: The alkali-free glass sheet according to claim 1, wherein the content of BaO is from 1.5 mol % to 2.5 mol %.

6: The alkali-free glass sheet according to claim 1, wherein the glass composition does not substantially contain As₂O₃ and Sb₂O₃, and further contains from 0.001 mol % to 1 mol % of SnO₂.

7: The alkali-free glass sheet according to claim 1, wherein a Young's modulus is 82 GPa or more, a strain point is 740° C. or higher, and a liquidus temperature is 1370° C. or lower.

8: The alkali-free glass sheet according to claim 1, wherein a strain point is 750° C. or higher.

9: The alkali-free glass sheet according to claim 1, wherein a Young's modulus is more than 83 GPa.

10: The alkali-free glass sheet according to claim 1, wherein an average thermal expansion coefficient in a temperature range of from 30° C. to 380° C. is from 30×10⁻⁷/° C. to 50×10⁻⁷/° C.

11: The alkali-free glass sheet according to claim 1, wherein a liquidus viscosity is 10^{4.2} dPa·s or more.

12: The alkali-free glass sheet according to claim 1, wherein an annealing point is 810° C. or higher.

13: The alkali-free glass sheet according to claim 1, which is for use in an organic EL device.

14: The alkali-free glass sheet according to claim 1, which is for use in a magnetic recording medium.
